(19) United States
(12) Patent Application Publication
(10) Pub. No.: US 2025/0006673 A1
(43) Pub. Date: Jan. 2, 2025

(54) Cooling Methodology for Package-on-Package Structures

(71) Applicant: Intel Corporation, Santa Clara, CA (US)

(72) Inventors: Siva Prasad JANGILI GANGA, Jagityal Dist (IN); Ajmeer Kaja AYUBKHAN, Bangalore (IN); Bharath Reddy GUDIGOPURAM, Nalgonda (IN)

(21) Appl. No.: 18/343,773

(22) Filed: Jun. 29, 2023

(51) Int. Cl. H01L 23/00; H01L 21/48; H01L 23/498; H05K 1/02

(52) U.S. Cl. CPC H01L 24/05; H01L 21/486; H01L 23/49827; H05K 1/0206; H01L 24/16; H01L 24/32; H01L 24/73; H01L 25/18; H01L 2224/05624; H01L 2224/05639; H01L 2224/05644; H01L 2224/05647; H01L 2224/16235; H01L 2224/32225; H01L 2224/73203; H01L 2924/1431; H05K 1/181; H05K 2201/10734

(57) ABSTRACT

The present disclosure is directed to package-on-package structures having a package substrate with an embedded logic package disposed on the package substrate and having heat conductive pathways being provided in the package-on-package structure for removing heat from the logic package. In an aspect, the heat conductive pathways enable a downward transfer of the heat generated by the logic package toward the package substrate. In another aspect, the heat conducting pathways may include a heat transfer layer formed proximally to a bottom surface of the logic package. In a further aspect, the heat conducting pathways may include one or more metal vias in the package substrate.

### BACKGROUND

For integrated circuit design and fabrication, the need to improve performance and lower costs are constant challenges. As transistors continue to shrink in size and are used in high-power and high-density semiconductors systems, for example, package-on-package structures, it is becoming increasingly difficult and costly to provide effective thermal management for such high-power and high-density semiconductors systems.

Electrical resistance is the main reason for the generation of heat in semiconductor devices, and high-power and high-density semiconductors systems provide less surface area to dissipate the generated heat. When a semiconductor system overheats, the devices and components with thermal ratings less than the generated temperature may be damaged. To avoid thermally-induced damage, the heat generated by the semiconductor system needs to be dissipated to its surrounding environment by a thermal transfer system.

Heat sinks are commonly used, as part of a thermal transfer system for high-power and high-density semiconductor systems, to provide additional surface area for heat dissipation. The use of heat sinks in combination with other thermal management devices, such as cooling fans, can provide the necessary heat dissipation rates for most high-power and high-density semiconductor systems. In most conventional thermal transfer systems remove the generated heat by the semiconductor system from the top of the package structure, i.e., coupling the heat sink to the package lid. For package-on-package structures, it may be difficult to provide thermal pathways that remove the generated heat from embedded logic devices to heat sinks positioned above the package structures or to other parts of the printed circuit boards.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a typical package-on-package structure;

FIGS. 2 and 2A show an exemplary representation of an embedded package cooling system and the heat conductive pathways formed for an embedded logic package according to an aspect of the present disclosure;

FIG. 3 shows an exemplary representation of heat conductive pathways between a logic package and a package substrate that includes various thermal vias, according to another aspect of the present disclosure;

FIG. 4 shows an exemplary representation of a buried metal via with a plurality of micro vias according to another aspect of the present disclosure;

FIGS. 5A and 5B show exemplary representations of buried metal vias and pluralities of micro vias according to yet another aspect of the present disclosure;

FIG. 6 shows a simplified flow diagram for an exemplary method according to an aspect of the present disclosure; and

FIG. 7 shows a photo of filled metal vias according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

As set forth in this disclosure, the present cooling elements and methodology are intended to remove heat from an embedded logic package in a semiconductor package-on-package (POP) structure to increase the performance of the POP structure. The present cooling elements draw the heat downward from the logic package to the underlying package substrate and printed circuit board. From the use of the present cooling methodology, the performance of the logic package, as well as the POP structure generally, will increase as optimal temperature conditions are better maintained.

In a further aspect, the present cooling elements may be made of a heat-conductive material, e.g., copper, aluminum, and other metals. The present cooling element may include one or more elements, such as a heat transfer layer or strand, that are formed in the logic package, a plurality of thermal vias that are formed in the package substrate and/or printed circuit board. If copper is used, for example, as the heat-conductive material, the thermal vias may be filled by an electroplating process or using a semi-solid paste through a paste printing process that employs pressure and heat. The semi-solid paste may be used to fill a thermal via opening and it will be sintered at a required temperature. Thereafter, upon cooling, the semi-solid paste will solidify to form an element of the heat conducting pathway.

Accordingly, the present disclosure provides a package-on-package structure having a package substrate with a logic package disposed on the package substrate, and heat conductive pathways being provided in the package-on-package structure for removing heat from the logic package. In an aspect, the heat conductive pathways enable a downward transfer of the heat generated by the logic package toward the package substrate and a printed circuit board (PCB). In another aspect, the heat conducting pathways may include a heat transfer layer formed proximally to a bottom surface of the logic package. In a further aspect, the heat conducting pathways may include one or more thermal vias in the package substrate and PCB.

The present disclosure is also directed to a method that includes providing a logic package, forming heat conductive pathways in a package substrate and a PCB, and disposing the logic package and the package substrate over the PCB. In an aspect, the logic package may be thermally coupled to the package substrate and PCB, by way of the heat conductive pathways, and a thermal differential directs the heat generated by the logic package downward along the heat conductive pathways toward the package substrate and PCB. In another aspect, the method includes disposing a second package over the logic package to form a package-on-package structure. In yet another aspect, the method includes forming a heat transfer layer proximal to a bottom surface of the logic package to facilitate the transfer of heat generated by the logic package and forming at least one metal via positioned in the package substrate, as elements of the heat conductive pathways.

The present disclosure is further directed to an embedded package cooling system having heat conductive pathways that are thermally coupled to a logic package, which is embedded in a package-on-package structure and disposed on a package substrate, for heat dissipation and enables a downward transfer of heat generated by the logic package toward the package substrate and PCB. In another aspect, the embedded package cooling system includes a heat transfer layer formed proximally to a bottom surface of the logic package and a plurality of metal vias formed in the package substrate as elements of the heat conductive pathways.

The technical advantages of the present disclosure include, but are not limited to:
(i) providing a cooling methodology for embedded logic packages in package-on-package (POP) structures;
(ii) providing heat dissipation from embedded logic packages along heat conductive pathways using structural features that direct the heat downward to the package substrate and printed circuit board; and
(iii) providing improved performance by reducing hot zones in the POP structures using the present cooling methodology.

To more readily understand and put into practical effect the present structural elements and method for cooling an embedded logic package, which may be used for improving the performance of package-on-package structures, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

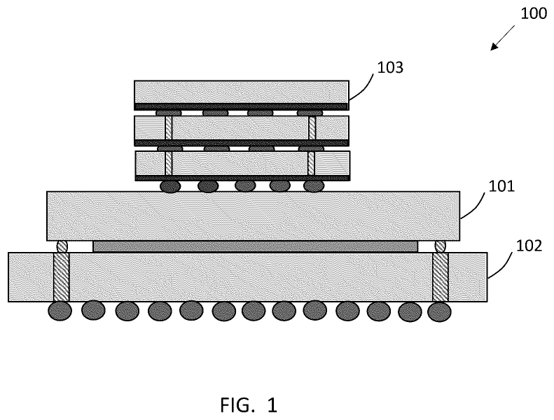

FIG. 1 shows an exemplary representation of a typical package-on-package (POP) structure 100 having a logic package 101 positioned on a package substrate 102, and a memory stack 103, i.e., a second package. The logic package 101 is “embedded” in that the memory stack 103 is disposed over the logic package 101. It should be understood that other types and sizes of semiconductor packages (typically non-logic packages) may be substituted for the memory stack 103 or additional packages may be disposed over the logic package 101. For such POP structures, the present disclosure provides an efficient cooling methodology that at least partially overcomes the impediment to the transfer of heat due to the presence of other packages or features in the POP structures and the embedded positioning of the logic package.

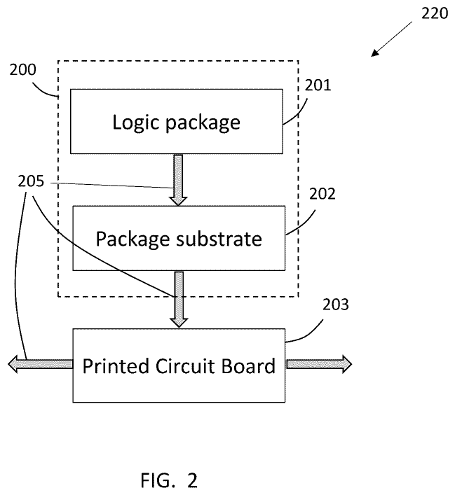

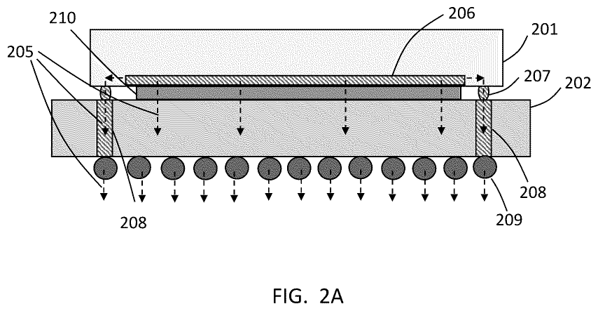

In FIG. 2, an exemplary representation of a POP structure 200 with an embedded package cooling system 220 for an embedded logic package 201 according to an aspect of the present disclosure. The embedded package cooling system 220 includes heat conductive pathways 205 that may lead from the embedded logic package 201 to a package substrate 202 and further to a printed circuit board (PCB) 203. The heat conductive pathways 205 may extend across the entirety of PCB 203 to dissipate the heat generated by the logic package 201. Although not shown, the additional or secondary packages that would be present in the POP structure 200 would typically be non-logic packages and would emit low amounts of heat as compared with the logic package 201.

FIG. 2A shows an exemplary representation of the logic package 201 that is positioned on the package substrate 202, both being shown in FIG. 2, according to an aspect of the present disclosure. The logic package 201 may be provided with a heat transfer layer 206, which may be located proximally to a bottom surface of the logic package 201. The heat transfer layer 206 may be, for example, one or more copper (Cu) strands, a solid or slotted thin Cu plate, or a coating of material with high thermal conductivity, i.e., silver, gold, aluminum, etc., and have dimensions as needed to provide the necessary thermal absorption and dissipation. The heat generated by the logic package 201 will flow downwards toward the heat transfer layer 206 and along heat conductive pathways 205 to the package substrate 202. The package substrate 202 may have one or more substrate thermal vias 208 that are thermally coupled by solder balls 207 to the logic package.

In an alternative aspect, which is not shown, a heat transfer layer may be positioned near the top of a logic package in a package-on-package structure. In this aspect, the heat transfer layer may be thermally coupled to a second package (non-logic package) by a non-metal thermal via (e.g., a silicon via) at the top of the logic package. The heat conductive pathways may be formed that lead from the second package in the package-on-package structure to direct the heat downward toward a package substrate having substrate thermal vias and further downward toward to a PCB having PCB thermal vias.

In another aspect, if there is a space between the logic package 201 and the package substrate 202, an underfilling 210 may be used to fill the space, which may also provide an additional heat conductive pathway 205 for heat dissipation. In a further aspect, a plurality of solder balls 209 may provide further heat conductive pathways 205 to the print circuit board 203 (not shown).

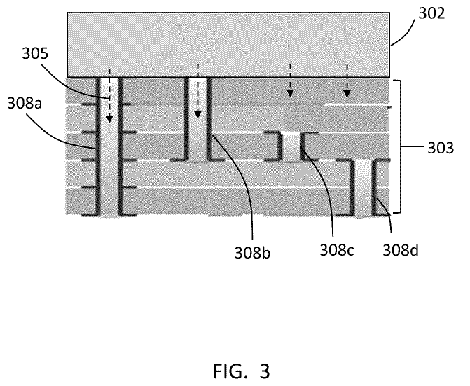

FIG. 3 shows an exemplary representation of the heat conductive pathways 305 formed between a package substrate 302 and printed circuit board (PCB) 303, which includes various thermal vias, according to another aspect of the present disclosure. In an aspect, the various PCB thermal vias may include through-hole vias 308a, top-side blind vias 308b, buried vias 308c, and bottom-side vias 308d. The present PCB thermal vias may have a diameter in the range of approximately 0.1 to 1 mm. It should be understood that a thermal via may be formed and used solely for heat dissipation and transfer, or have a dual use, such as lines for signals, power, grounds, etc.

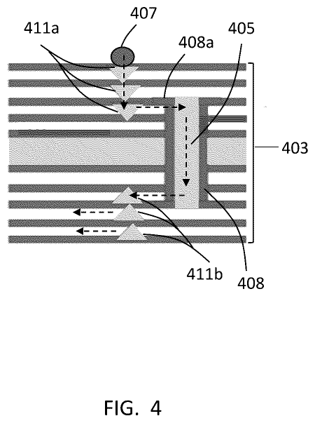

FIG. 4 shows an exemplary representation of a buried metal via 408 with a plurality of micro vias 411a and 411b that form a heat conductive pathway 405 in PCB 403 according to another aspect of the present disclosure. A solder ball 407 may be used to connect the micro vias 411a to a package substrate (not shown). According to the present disclosure, a PCB thermal via may be formed by a combination of the micro vias 411a, the buried metal via 408, and the micro vias 411b in the package substrate 402. For example, the buried metal via 408 may have a diameter of approximately 200 μm, with end pads 408a having a diameter of approximately 400 μm.

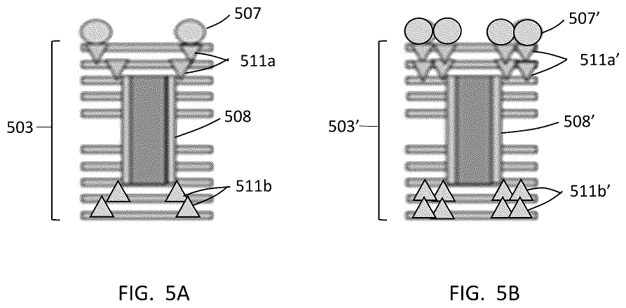

FIG. 5A shows an exemplary representation of a PCB thermal via formed by a buried metal via 508 and a top set of micro vias 511a and a bottom set of micro vias 511b, and FIG. 5B shows another exemplary representation of another PCB thermal via formed by a buried metal via 508′ and a top set of micro vias 511a′ and a bottom set of micro vias 511b′ according to another aspect of the present disclosure.

In FIG. 5A, the micro vias 511a and 511b may be configured diagonally to thermally couple with the buried metal via 508 and have a set of solder balls 507 connecting to the micro vias 511a to a package substrate and logic package (both not shown). In FIG. 5B, the micro vias 511a′ and 511b″ may be configured as clusters, respectively, near the top and bottom of the buried metal via 508′. The micro vias 511a′ may have a set of solder balls 507′ connecting to the micro vias 511a′ to a package substrate and logic package (both not shown).

As shown in FIGS. 5A and 5B, the configuration of the micro vias may be designed to provide the heat conductive pathways with different capacities for heat dissipation. For example, the micro vias may have a diameter of approximately 100 μm and the buried vias may have a diameter of approximately 400 μm to provide sufficient heat conductive properties. The heat conductive pathways may extend between the micro vias and the buried vias by direct contact and/or by ground layers or routing layers therebetween.

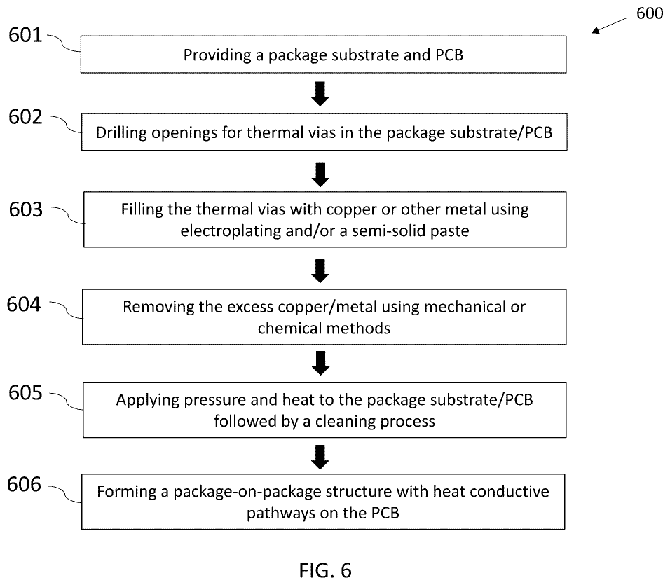

FIG. 6 shows a simplified flow diagram for an exemplary method 600 according to an aspect of the present disclosure.

The operation 601 may be directed to providing a package substrate and PCB.

The operation 602 may be directed to drilling openings for thermal vias in the package substrate/PCB. The size of the drill openings may be approximately 4 mm.

The operation 603 may be directed to filling the thermal vias with copper or other metal using electroplating and/or a semi-solid paste, e.g., Cu paste LTV 54M. It should be understood that other conventional methods/processes may be used to form the thermal vias. The filling process may be from the top or below.

The operation 604 may be directed to removing the excess copper/metal using mechanical or chemical methods.

The operation 605 may be directed to applying pressure and heat to the package substrate/PCB followed by a cleaning process. For example, the pressure may be 1.0 MT for 40 minutes at a curing temperature of 225° C.

The operation 606 may be directed to forming a package-on-package structure with heat conductive pathways on the PCB.

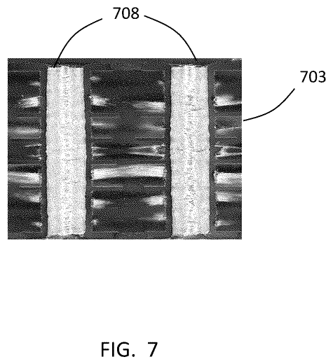

FIG. 7 shows a photo of metal PCB thermal vias 708 in a printed circuit board 703 according to an aspect of the present disclosure. In an aspect, the PCB thermal vias 708 may be formed and filled with copper as described above and may be used as elements of the present heat conductive pathways.

In another aspect, the present cooling methodology may be able to reduce z-direction warpage with the use of thermal vias in the printed circuit board (PCB). For simulations using a plurality of thermal vias (e.g., 52 vias) having a similar structure to that shown in FIG. 4, with a diameter of approximately 0.4 mm that is positioned in a PCB having a thickness of 0.61 mm, the warpage was reduced from 0.107 mm (without the thermal vias) to 0.095 mm (with the thermal vias).

It will be understood that any property described herein for a particular package-on-package structure and cooling method for embedded logic packages may also hold for any other package-on-package structure using the cooling methodology described herein. It will also be understood that any property described herein for a specific method may hold for any of the methods described herein. Furthermore, it will be understood that for any of the heat conductive pathways and the methods described herein, not necessarily all the components or operations described will be shown in the accompanying drawings or method, but only some (not all) components or operations may be disclosed.

To more readily understand and put into practical effect the present semiconductor carrier platforms and thermal stability layers, they will now be described by way of examples. For the sake of brevity, duplicate descriptions of features and properties may be omitted.

### Examples

Example 1 provides a package-on-package structure including a package substrate, a logic package disposed on the package substrate, and heat conductive pathways provided in the package-on-package structure and coupled to the logic package for removing heat from the logic package, for which the heat conductive pathways enable a downward transfer of heat generated by the logic package towards the package substrate and a printed circuit board, for which the heat conductive pathways enable a downward transfer of heat generated by the logic package towards the printed circuit board.

Example 2 may include the package-on-package structure of example 1 and/or any other example disclosed herein, for which the heat conducting pathways include a heat transfer layer formed proximally to a bottom surface of the logic package.

Example 3 may include the package-on-package structure of example 1 and/or any other example disclosed herein, for which the heat conducting pathways include at least one substrate thermal via in the package substrate and the logic package is thermally coupled to the at least one substrate thermal via.

Example 4 may include the package-on-package structure of example 3 and/or any other example disclosed herein, for which the heat conducting pathways comprise at least one PCB thermal via in the PCB and the logic package is thermally coupled to the at least one PCB thermal via.

Example 5 may include the package-on-package structure of example 3 and/or any other example disclosed herein, for which the at least one substrate thermal via is a through-hole.

Example 6 may include the package-on-package structure of example 4 and/or any other example disclosed herein, for which the at least one PCB thermal via is a through-hole via, blind via, or buried via.

Example 7 may include the package-on-package structure of example 6 and/or any other example disclosed herein, for which the least one PCB thermal via is a buried via wherein the buried via is coupled to a plurality of micro vias.

Example 8 may include the package-on-package structure of example 4 and/or any other example disclosed herein, for which the at least one PCB thermal via is formed of a copper material.

Example 9 may include the package-on-package structure of example 3 and/or any other example disclosed herein, for which the at least one PCB thermal via provides a ground connection.

Example 10 may include the package-on-package structure of example 1 and/or any other example disclosed herein, for which the logic package is embedded in the package-on-package structure.

Example 11 provides a method that includes providing a logic package, forming heat conductive pathways in a package substrate, forming heat conductive pathways in a PCB, disposing the logic package over the package substrate, disposing a second package over the logic package to form a package-on-package structure, disposing the logic package and package substrate over the PCB, for which the logic package is thermally coupled to the package substrate and the PCB, and providing a thermal differential that directs heat generated by the logic package downward along the heat conductive pathways toward the package substrate and the PCB.

Example 12 may include the method of example 11 and/or any other example disclosed herein, for which the forming heat conductive pathways further includes forming a heat transfer layer proximal to a bottom surface of the logic package, for which the heat transfer layer facilitates the transfer of heat generated by the logic package.

Example 13 may include the method of example 11 and/or any other example disclosed herein, for which the forming heat conductive pathways further includes forming at least one metal via in the package substrate.

Example 14 may include the method of example 13 and/or any other example disclosed herein, for which the forming at least one substrate thermal via in the package substrate further includes drilling a substrate via opening in the package substrate and filling the substrate via opening with copper.

Example 15 may include the method of example 13 and/or any other example disclosed herein, for which the forming at least one PCB thermal via in the PCB further comprises drilling a PCB via opening in the PCB and filling the PCB via opening with copper.

Example 16 may include the method of example 14 and/or any other example disclosed herein, for which the heat conductive pathway further includes forming a plurality of micro vias in the package substrate that are thermally coupled to the at least one PCB thermal via.

Example 17 provides a package cooling system including heat conductive pathways that are thermally coupled to a logic package for heat dissipation, for which the embedded logic package is embedded in a package-on-package structure and disposed on a package substrate and a printed circuit board coupled to the heat conductive pathways that enable a downward transfer of heat generated by the logic package toward the package substrate and the PCB.

Example 18 may include the package cooling system of example 17 and/or any other example disclosed herein, for which the heat conductive pathways further include a heat transfer layer formed proximally to a bottom surface of the logic package.

Example 19 may include the package cooling system of example 17 and/or any other example disclosed herein, for which the heat conductive pathways further include a substrate thermal via formed in the package substrate and a PCB thermal via formed in the PCB.

Example 20 may include the package cooling system of example 19 and/or any other example disclosed herein, for which the heat conductive pathways further include a plurality of micro vias in the package substrate that are thermally coupled to the PCB thermal via in the PCB.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A package-on-package structure comprising:
a package substrate;
a logic package disposed on the package substrate;
heat conductive pathways provided in the package-on-package structure and coupled to the logic package for removing heat from the logic package, wherein the heat conductive pathways enable a downward transfer of heat generated by the logic package towards the package substrate; and
a printed circuit board, wherein the heat conductive pathways enable a downward transfer of heat generated by the logic package towards the printed circuit board (PCB).

2. The package-on-package structure of claim 1, wherein the heat conducting pathways comprise a heat transfer layer formed proximally to a bottom surface of the logic package.

3. The package-on-package structure of claim 1, wherein the heat conducting pathways comprise at least one substrate thermal via in the package substrate and the logic package is thermally coupled to the at least one substrate thermal via.

4. The package-on-package structure of claim 3, wherein the heat conducting pathways comprise at least one PCB thermal via in the PCB and the logic package is thermally coupled to the at least one PCB thermal via.

5. The package-on-package structure of claim 3, wherein the at least one substrate thermal via is a through-hole via.

6. The package-on-package structure of claim 4, wherein the at least one PCB thermal via is a through-hole via, blind via, or buried via.

7. The package-on-package structure of claim 6, wherein the least one PCB thermal via is a buried via wherein the buried via is coupled to a plurality of micro vias.

8. The package-on-package structure of claim 4, wherein the at least one PCB thermal via is formed of a copper material.

9. The package-on-package structure of claim 4, wherein the at least one PCB thermal via provides a ground connection.

10. The package-on-package structure of claim 1, wherein the logic package is embedded in the package-on-package structure.

11. A method comprising:
providing a logic package;
forming heat conductive pathways in a package substrate and in a printed circuit board (PCB);
disposing the logic package over the package substrate;
disposing a second package over the logic package to form a package-on-package structure;
disposing the logic package and package substrate over the PCB, wherein the logic package is thermally coupled to the package substrate and the PCB; and
providing a thermal differential that directs heat generated by the logic package downward along the heat conductive pathways toward the package substrate and the PCB.

12. The method of claim 11, wherein the forming heat conductive pathways further comprises forming a heat transfer layer proximal to a bottom surface of the logic package, wherein the heat transfer layer facilitates transfer of heat generated by the logic package.

13. The method of claim 11, wherein the forming heat conductive pathways in the package substrate and the PCB further comprises forming at least one substrate thermal via in the package substrate and forming at least one PCB thermal via in the PCB, respectively.

14. The method of claim 13, wherein the forming at least one substrate thermal via in the package substrate further comprises drilling a substrate via opening in the package substrate and filling the substrate via opening with copper.

15. The method of claim 13, wherein the forming at least one PCB thermal via in the PCB further comprises drilling a PCB via opening in the PCB and filling the PCB via opening with copper.

16. The method of claim 14, wherein forming the heat conductive pathways further comprises:
forming a plurality of micro vias in the package substrate that are thermally coupled to the at least one PCB thermal via.

17. A package cooling system comprising:
heat conductive pathways that are thermally coupled to a logic package for heat dissipation, wherein the logic package is embedded in a package-on-package structure and disposed on a package substrate; and
a printed circuit board (PCB) coupled to the heat conductive pathways that enable a downward transfer of heat generated by the logic package toward the package substrate and the PCB.

18. The package cooling system of claim 17, wherein the heat conductive pathways further comprise a heat transfer layer formed proximally to a bottom surface of the logic package.

19. The package cooling system of claim 17, wherein the heat conductive pathways further comprise a substrate thermal via formed in the package substrate and a PCB thermal via formed in the PCB.

20. The package cooling system of claim 19, wherein the heat conductive pathways further comprise a plurality of micro vias in the package substrate that are thermally coupled to the PCB thermal via in the PCB.
